(19) United States
(12) Patent Application Publication
(10) Pub. No.: US 2006/0254790 A1
(43) Pub. Date: Nov. 16, 2006

(54) Cooling unit having heat radiating portion, through which liquid coolant flows and electronic apparatus equipped with cooling unit

(76) Inventors: Yukihiko Hata, Hamura-shi (JP); Kentaro Tomioka, Sayama-shi (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/473,882

(22) Filed: Jun. 22, 2006

Related U.S. Application Data
(63) Continuation of application No. PCT/JP04/18738, filed on Dec. 15, 2004.

(30) Foreign Application Priority Data
Dec. 25, 2003 (JP) 2003-431031

(51) Int. Cl. H05K 7/20

(52) U.S. Cl. 174/16.3

(57) ABSTRACT

A cooling unit includes a heat receiving portion thermally connected to a heat generating component, a heat radiating portion which radiates heat generated by the heat generating component, and a circulation path which circulates a liquid coolant between the heat receiving portion and the heat radiating portion. The heat radiating portion includes a first path portion, a second path portion, a third path portion, and a plurality of heat radiating fins. Each of the first and second path portions has a flat pipe through which the liquid coolant flows. The two pipes have cross sections which are elongated in the same direction and facing each other. The heat radiating fins are interposed between the two pipes and thermally connected to the two pipes.

### CROSS REFERENCE TO RELATED APPLICATIONS

This is a Continuation Application of PCT Application No. PCT/JP2004/018738, filed Dec. 15, 2004, which was published under PCT Article 21(2) in Japanese.

This application is based upon and claims the benefit of priority from Japanese Patent Application No. 2003-431031, filed Dec. 25, 2003, the entire contents of which are incorporated herein by reference.

### BACKGROUND

1. Field

One embodiment of the invention relates to a cooling unit of a liquid cooling type, which cools a heat generating component, such as a CPU, by means of a liquid coolant, and to an electronic apparatus equipped with the cooling unit.

2. Description of the Related Art

A CPU is incorporated in an electronic apparatus, for example, a portable computer. The CPU tends to generate increased heat during operation, as the processing speed is increased or the functions thereof are expanded. If the temperature of the CPU rises too high, the CPU cannot operate efficiently or may be brought down.

To cool the CPU, recently, a so-called cooling system of a liquid cooling type has been put into practical use. In this type of cooling system, the CPU is cooled by a coolant, whose specific heat is much higher than that of air.

The conventional cooling system has a heat receiving portion which receives heat from a CPU, a heat radiating portion which radiates the heat received from the CPU, and a circulation path which circulates a liquid coolant between the heat receiving portion and the heat radiating portion. The heat radiating portion has a pipe, which passes the liquid coolant that has been heated by heat exchange with the heat receiving portion, and a plurality of flat plate heat radiating fins. The heat radiating fins are arranged parallel at intervals. The pipe passes through the central portion of the heat radiating fins. The periphery of the pipe is thermally connected to the central portion of the heat radiating fins by means of, for example, soldering. For example, Jpn. Pat. Appln. KOKAI Publication No. 2003-101272 discloses an electronic apparatus equipped with a cooling unit having such a heat radiating portion.

The heat radiating performance of the heat radiating portion is determined depending on how much the heat absorbed by the liquid coolant is transmitted to the heat radiating fins. In the conventional heat radiating portion, the pipe passes through the central portion of the heat radiating fins. Therefore, the heat of the liquid coolant passing through the pipe is transmitted to the heat radiating fins radially via the periphery of the pipe.

The pipe, through which the liquid coolant flows, has an outer diameter of at most about 5-8 mm. Therefore, the contact area where the pipe is in contact with the heat radiating fins cannot be sufficiently large, and the heat of the liquid coolant cannot easily be transmitted from the pipe to all parts of the heat radiating fins. As a result, the surface temperature of the heat radiating fins cannot fully rise, so that the heat of the CPU cannot be efficiently radiated through the heat radiating portion.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a perspective view of an exemplary portable computer according to a first embodiment of the present invention;

FIG. 2 is an exemplary perspective view of the portable computer according to the first embodiment of the present invention, which shows the position of exhaust ports of a first housing;

FIG. 3 is an exemplary plan view of a cooling unit housed in the first housing according to the first embodiment of the present invention;

FIG. 4 is an exemplary sectional view showing the positional relationship between a pump unit and a printed circuit board having the CPU according to the first embodiment of the present invention;

FIG. 5 is an exemplary exploded perspective view showing the pump unit according to the first embodiment of the present invention;

FIG. 6 is an exemplary perspective view of a pump housing according to the first embodiment of the present invention;

FIG. 7 is an exemplary plan view of the housing body of the pump housing according to the first embodiment of the present invention;

FIG. 8 is an exemplary perspective view of the heat radiating portion of the cooling unit according to the first embodiment of the present invention;

FIG. 9 is an exemplary sectional view taken along the line F9-F9 in FIG. 3;

FIG. 10 is an exemplary sectional view taken along the line F10-F10 in FIG. 3;

FIG. 11 is an exemplary sectional view of a heat radiating portion according to a second embodiment of the present invention; and

FIG. 12 is an exemplary plan view of a cooling unit housed in the first housing according to a third embodiment of the present invention.

### DETAILED DESCRIPTION

Various embodiments according to the invention will be described hereinafter with reference to the accompanying drawings. In general, according to one embodiment of the invention, a cooling unit includes a heat receiving portion thermally connected to a heat generating component, a heat radiating portion which radiated heat generated by the heat generating component, and a circulation path which circulated a liquid coolant between the heat receiving portion and the heat radiating portion. The heat radiating portion includes a first path portion, a second path portion, a third path portion connecting the first path portion and the second path portion, and a plurality of heat radiating fins. Each of the first and second path portions has a flat pipe through which the liquid coolant flows. The two pipes have cross section which are elongated in the same direction and facing each other. The heat radiating fins are interposed between the two pipes and thermally connected to the two pipes.

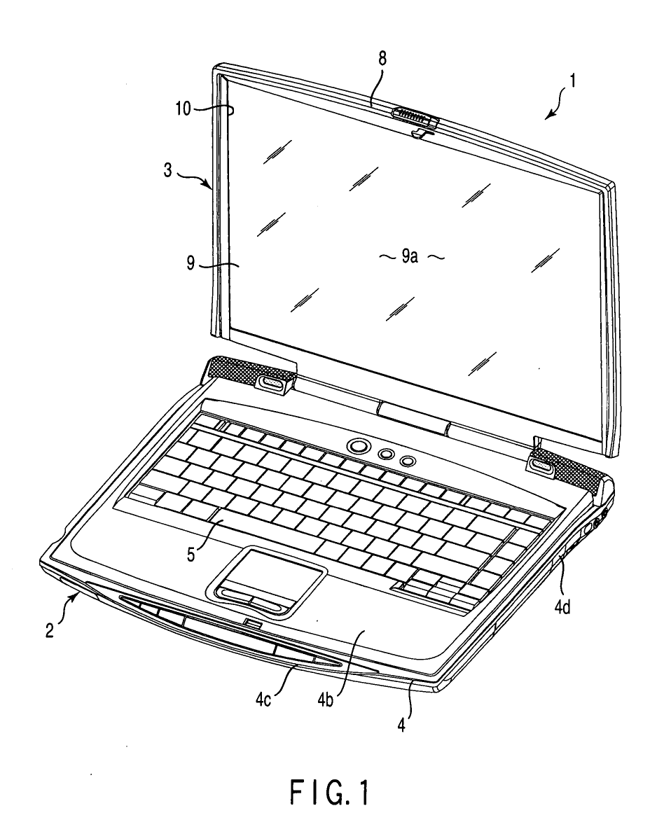

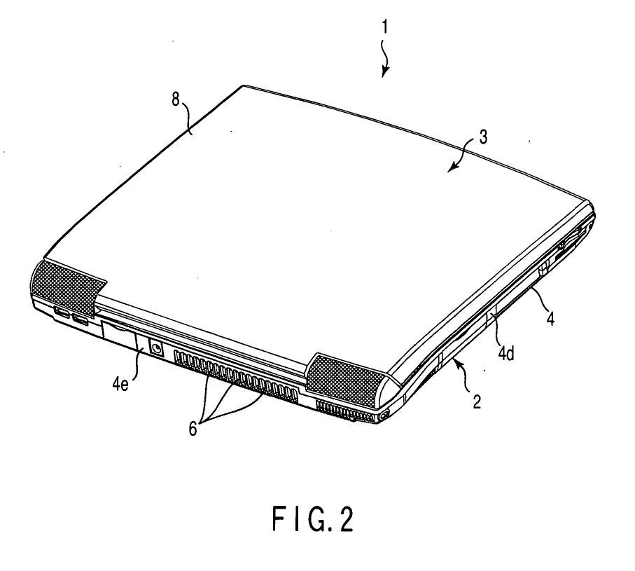

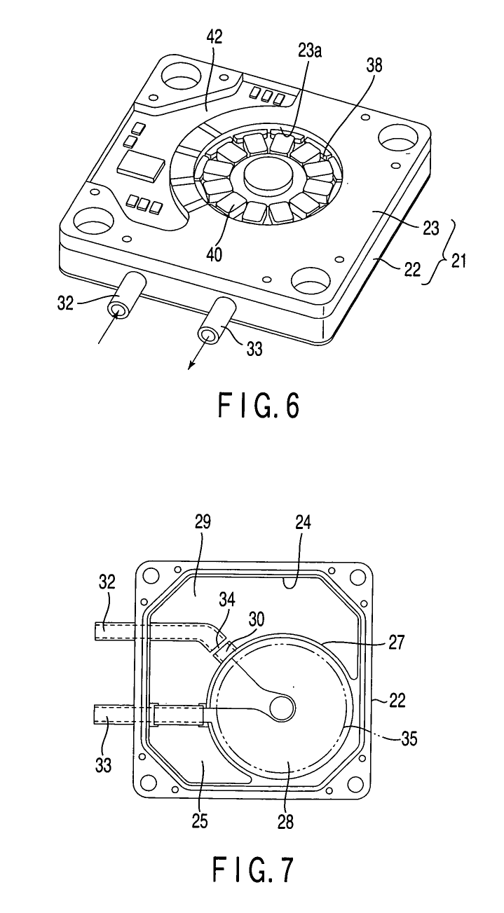

A first embodiment of the present invention will be described with reference to FIGS. 1 to 10.

FIG. 1 discloses a portable computer 1 as an electronic apparatus. The portable computer 1 comprises a main unit 2 and a display unit 3. The main unit 2 has a flat box-shaped first housing 4. The first housing 4 has a bottom wall 4a, an upper wall 4b, a front wall 4c, left and right side walls 4d and a rear wall 4e. The front wall 4c, the left and right side walls 4d and the rear wall 4e constitute a peripheral wall of the first housing 4. The upper wall 4b of the first housing 4 supports a keyboard 5. A plurality of exhaust ports 6 are formed in the rear wall 4e of the first housing 4. The exhaust ports 6 are arranged in a line in the width direction of the first housing 4.

The display unit 3 has a second housing 8 and a liquid crystal display panel 9. The liquid crystal display panel 9 is housed in the second housing 8. The liquid crystal display panel 9 has a screen 9a, which displays an image. The screen 9a is exposed to the outside of the second housing 8 through an opening 10 formed in the front surface of the second housing 8.

The second housing 8 of the display unit 3 is supported by the rear end portion of the first housing 4 via a hinge (not shown). The display unit 3 is rotatable between a closed position and an open position. In the closed position, the display unit 3 lies on the main unit 2 to cover the keyboard 5 from above. In the open position, the display unit 3 stands relative to the main unit 2 so as to expose the keyboard 5 and the screen 9a.

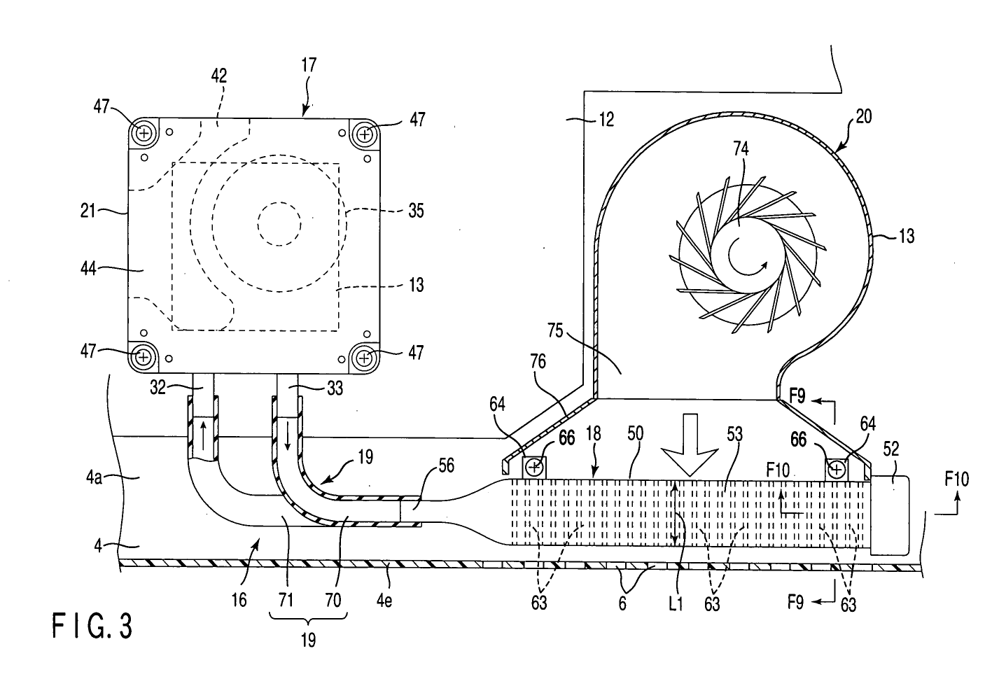

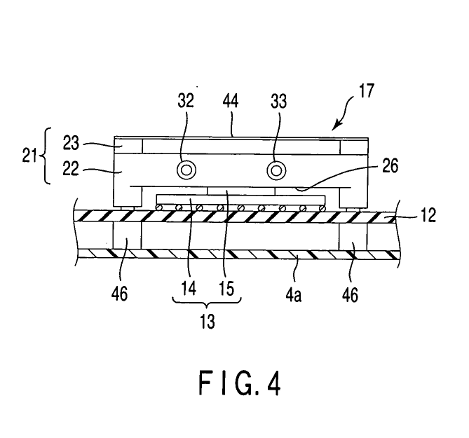

As shown in FIGS. 3 and 4, the first housing 4 houses the printed circuit board 12. The printed circuit board 12 is disposed parallel to the bottom wall 4a of the first housing 4. A CPU 13, as a heat generating component, is mounted on the upper surface of the printed circuit board 12. The CPU 13 has a square base 14 and an IC chip 15. The IC chip 15 is mounted on a central portion of the upper surface of the square base 14. The IC chip 15 generates a great amount of heat, as it is operated at a high processing speed and has many functions. Therefore, the IC chip 15 needs cooling to maintain stable operations.

As shown in FIG. 3, the main unit 2 contains a cooling unit 16 of a liquid cooling type. The cooling unit 16 cools the CPU 13 by means of a liquid coolant, such as an antifreezing solution. The cooling unit 16 includes a pump unit 17, a heat radiating portion 18, a circulation path 19 and an electric fan 20.

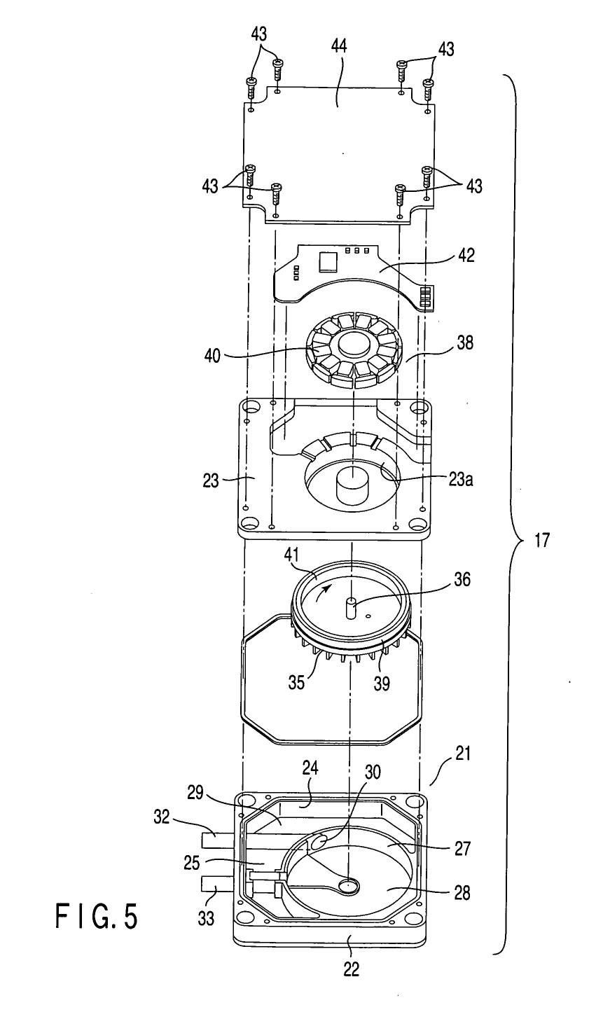

As shown in FIGS. 5 to 7, the pump unit 17 has a pump housing 21, which serves also as a heat receiving portion. The pump housing 21 has a box shape having four corners. The pump housing 21 has a housing body 22 and a top cover 23. The housing body 22 is made of metal having a high thermal conductivity, for example, an aluminum alloy. The housing body 22 has a recess portion 24, which opens upward. A bottom wall 25 of the recess portion 24 faces the CPU 13. The lower surface of the bottom wall 25 is a flat heat receiving surface 26. The top cover 23 is made of a synthetic resin, and liquid-tightly closes the open end of the recess portion 24.

The interior of the pump housing 21 is divided into a pump chamber 28 and a reserve tank 29 by a ring-shaped division wall 27. The reserve tank 29, for storing a liquid coolant, surrounds the pump chamber 28. The division wall 27 stands upright from the bottom wall 25 of the housing body 22. The division wall 27 has a communication port 30. The pump chamber 28 and the reserve tank 29 communicate with each other via the communication port 30.

An inlet pipe 32 and an outlet pipe 33 are formed integral with the housing body 22. The inlet pipe 32 and the outlet pipe 33 are arranged parallel with a distance therebetween. The upstream end of the inlet pipe 32 projects outward from a side surface of the housing body 22. The downstream end of the inlet pipe 32 is open to the reserve tank 29 and faces the communication port 30 of the division wall 27. As shown in FIG. 7, a gas-liquid separating gap 34 is formed between the downstream end of the inlet pipe 32 and the communication port 30. The gap 34 is always located under the liquid surface of the liquid coolant stored in the reserve tank 29, regardless of the posture of the pump housing 21.

The downstream end of the outlet pipe 33 projects outward from the side surface of the housing body 22, and aligns with the upstream end of the inlet pipe 32. The upstream end of the outlet pipe 33 is open to the pump chamber 28 through the division wall 27.

The pump chamber 28 of the pump housing 21 stores a disk-shaped impeller 35. The impeller 35 has a rotation shaft 36 at the center of rotation thereof. The rotation shaft 36 extends between the bottom wall 25 of the housing body 22 and the top cover 23, and is rotatably supported by the bottom wall 25 and the top cover 23.

The pump housing 21 incorporates a motor 38, which drives the impeller 35. The motor 38 has a rotor 39 and a stator 40. The rotor 39 is ring-shaped. The rotor 39 is coaxially fixed to the upper surface of the impeller 35, and housed in the pump chamber 28. A magnet 41 is fitted in the rotor 39. The magnet 41 has a plurality of positive poles and a plurality of negative poles arranged alternately. The magnet 41 rotates integrally with the rotor 39 and the impeller 35.

The stator 40 is held in a recess 23a formed in the upper surface of the top cover 23. The recess 23a gets in the rotor 39. Thus, the stator 40 is coaxially fitted in the rotor 39. A control board 42, which controls the motor 38, is supported by the upper surface of the top cover 23. The control board 42 is electrically connected to the stator 40.

Power supply to the stator 40 is carried out, for example, at the same time as the portable computer 1 is powered on. The power supply generates a rotary magnetic field in the circumferential direction of the stator 40. The magnetic field magnetically couples with the magnet 41 of the rotor 39. As a result, rotary torque along the circumferential direction of the rotor 39 is generated between the stator 40 and the magnet 41, and the impeller 35 rotates clockwise in the direction of the arrow shown in FIG. 5.

A back plate 44 is fixed to the upper surface of the top cover 23 by a plurality of screws 43. The back plate 44 covers the stator 40 and the control board 42.

As shown in FIG. 4, the pump unit 17 is mounted on the printed circuit board 12 so as to cover the CPU 13 from above. The pump housing 21 of the pump unit 17 is fixed to the bottom wall 4a of the first housing 4 together with the printed circuit board 12. The bottom wall 4a has boss portions 46 in the positions corresponding to the four corner portions of the pump housing 21. The boss portions 46 project upward from the bottom wall 4a. The printed circuit board 12 is placed on the top ends of the boss portions 46.

Screws 47 are inserted in the four corner portions of the pump housing 21 from above. The screws 47 are screwed into the boss portions 46 through the top cover 23, the housing body 22 and the printed circuit board 12. The pump unit 17 and the printed circuit board 12 are fixed to the bottom wall 4a by the screwing, and the heat receiving surface 26 of the housing body 22 is thermally connected to the IC chip 15 of the CPU 13.

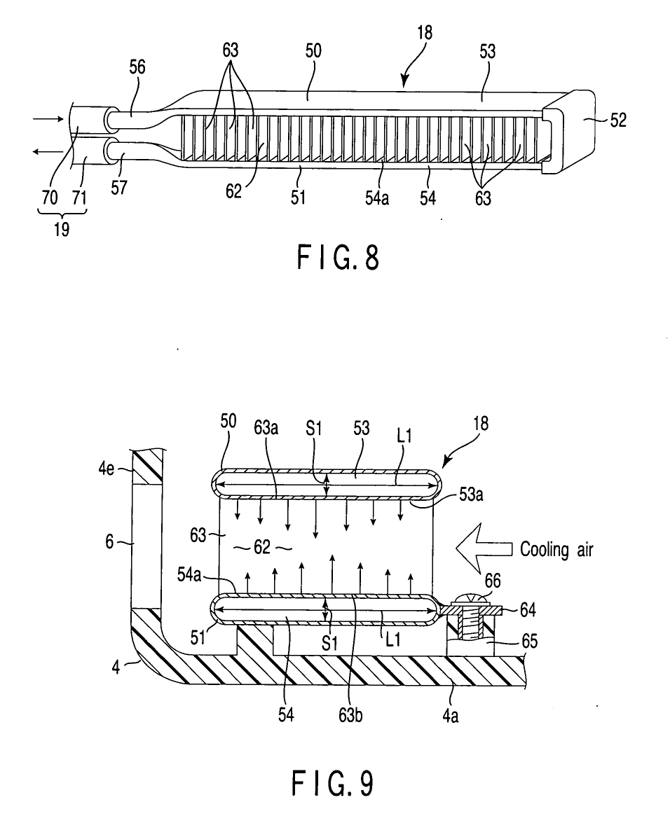

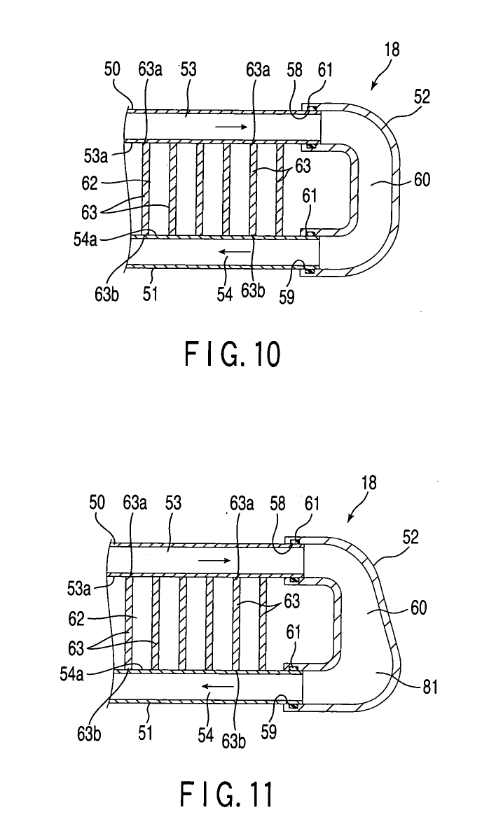

As shown in FIGS. 8 and 10, the heat radiating portion 18 of the cooling unit 16 has first to third path portions 50 to 52, through which the liquid coolant flows. The first and second path portions 50 and 51 are parallel to the bottom wall 4a of the first housing 4: more specifically, in this embodiment, they extend in the width direction of the first housing 4. The first and second path portions 50 and 51 respectively have flat pipes 53 and 54. The pipes 53 and 54 are made of metal, which has high thermal conductivity, for example, copper. The pipes 53 and 54 have cross sections, which are elongated in the same direction. In other words, each of the pipes 53 and 54 has a long axis L1, which is parallel to the bottom wall 4a of the first housing 4, and a short axis S1, which extends along the thickness direction of the first housing 4.

The pipe 53 of the first path portion 50 and the pipe 54 of the second path portion 51 face each other with a distance therebetween in the width direction of the first housing 4, such that the long axes L1 of the two pipes are parallel to each other. The pipe 53 of the first path portion 50 is located above the pipe 54 of the second path portion 51. The pipes 53 and 54 respectively have flat support surfaces 53a and 54a, which face each other.

The upstream end of the pipe 53 forms a coolant inlet port 56, through which the liquid coolant flows in. The coolant inlet port 56 has a circular cross section. The downstream end of the pipe 53 has a flat cross section. The downstream end of the pipe 54 forms a coolant outlet port 57, through which the liquid coolant flows out. The coolant outlet port 57 has a circular cross section. The upstream end of the pipe 54 has a flat cross section. The coolant inlet port 56 and the coolant outlet port 57 are arranged with a distance therebetween in the thickness direction of the first housing 4.

As shown in FIG. 10, the third path portion 52 connects the downstream end of the pipe 53 and the upstream end of the pipe 54. The third path portion 52 is an injection molded product made of, for example, an aluminum alloy or synthetic resin. The third path portion 52 has a first connection port 58 which is engaged with the downstream end of the pipe 53, a second connection port 59 which is engaged with the upstream end of the pipe 54, and a communication path 60 connecting the first connection port 58 and the second connection port 59. The communication path 60 extends in the thickness direction of the first housing 4.

An O-ring 61 is fitted to the inner periphery of each of the first and second connection ports 58 and 59. The O-rings 61 adhere closely to the outer periphery of the downstream end of the pipe 53 and the outer periphery of the upstream end of the pipe 54. In other words, the O-rings 61 liquid-tightly seal the connecting portion between the first path portion 50 and the third path portion 52 and the connecting portion between the second path portion 51 and the third path portion 52.

As shown in FIGS. 8 to 10, a cooling air path 62 is formed between the pipe 53 of the first path portion 50 and the pipe 54 of the second path portion 51. A plurality of heat radiating fins 63 are provided in the cooling air path 62. Each of the hear radiating fins 63 is a rectangular plate, made of metal having a high thermal conductivity, for example, an aluminum alloy or copper. The heat radiating fins 63 are interposed between the pipes 53 and 54 and exposed to the cooling air path 62. The heat radiating fins 63 are arranged parallel to one another at intervals in the posture along the long axes L1 of the pipes 53 and 54.

The heat radiating fin 63 has a first edge 63a and a second edge 63b, which is located at the opposite end from the first edge 63a. The first and second edges 63a and 63b are parallel to each other. The first edge 63a of the heat radiating fin 63 is soldered to the support surface 53a of the pipe 53. The second edge 63b of the heat radiating fin 63 is soldered to the support surface 54a of the pipe 54. Thus, the first to third path portions 50 to 52 and the heat radiating fins 63 are assembled into one integral structure, and the heat radiating fins 63 are thermally connected to the pipes 53 and 54.

As shown in FIG. 3, the heat radiating portion 18 is housed in the first housing 4 in a horizontal posture along the rear wall 4e of the first housing 4. The heat radiating fins 63 of the heat radiating portion 18 faces the exhaust ports 6. The second path portion 51 of the heat radiating portion 18 is located above the bottom wall 4a of the first housing 4. A pair of brackets 64 is soldered to an edge portion of the pipe 54 of the second path portion 51. The brackets 64 are separated from each other in the longitudinal direction of the second path portion 51, and fixed to boss portions 65 protruded from the bottom wall 4a by screws 66.

Thus, the heat radiating portion 18 is fixed to the bottom wall 4a of the first housing 4, and the heat radiating fins 63 extend straight along the depth direction of the first housing 4.

As shown in FIG. 3, the circulation path 19 has a first pipe 70 and a second pipe 71. The first pipe 70 connects the outlet pipe 33 of the pump housing 21 and the coolant inlet port 56 of the heat radiating portion 18. The second pipe 71 connects the inlet pipe 32 of the pump housing 21 and the coolant outlet port 57 of the heat radiating portion 18. The liquid coolant circulates between the pump housing 21 and the heat radiating portion 18 through the first and second pipes 70 and 71.

The electric fan 20 supplies cooling air to the heat radiating portion 18. It is located just in front of the heat radiating portion 18. The electric fan 20 has a fan casing 73, and a centrifugal impeller 74 housed in the fan casing 73. The fan casing 73 has a discharge port 75, through which the cooling air is discharged. The discharge port 75 communicates with the cooling air path 62 of the heat radiating portion 18 via an air guide duct 76.

The impeller 74 is driven by a motor (not shown), when the portable computer 1 is powered on or the temperature of the CPU 13 reaches a predetermined value. The impeller 74 is rotated by the motor, so that the cooling air is supplied to the cooling air path 62 from the discharge port 75 of the fan casing 73.

An operation of the cooling unit 16 will now be described.

When the portable computer is used, the IC chip 15 of the CPU 13 generates heat. The heat generated by the IC chip 15 is transmitted to the pump housing 21 via the heat receiving surface 26. The pump chamber 28 and the reserve tank 29 of the pump housing 21 are filled with the liquid coolant. Therefore, the liquid coolant absorbs most of the heat transmitted to the pump housing 21.

Power is supplied to the stator 40 of the motor 38 at the same time as the portable computer 1 is powered on. As a result, torque is generated between the stator 40 and the magnet 41 of the rotor 39, thereby rotating the rotor 39 together with the impeller 35. When the impeller 35 is rotated, the liquid coolant in the pump chamber 28 is pressurized and discharged through the outlet pipe 33. The liquid coolant is guided from the outlet pipe 33 to the heat radiating portion 18 through the first pipe 70.

More specifically, the liquid coolant heated by the heat exchange in the pump housing 21 is first supplied to the first path portion 50 from the coolant inlet port 56 of the heat radiating portion 18. The liquid coolant flows from the first path portion 50 to the second path portion 51 via the third path portion 52. The heat of the IC chip 15, which is absorbed by the liquid coolant in the process of this flow, is transmitted to the pipe 53 of the first path portion 50 and the pipe 54 of the second path portion 51. Further, the heat is transmitted from the pipes 53 and 54 to the heat radiating fins 63.

During the use of the portable computer 1, when the impeller 74 of the electric fan 20 rotates, cooling air blows from the discharge port 75 of the fan casing 73 toward the cooling air path 62 of the heat radiating portion 18. The cooling air passes between the adjacent hear radiating fins 63 in the process of flowing through the cooling air path 62. As a result, the heat radiating fins 63 and the pipes 53 and 54 are cooled, and most part of the heat transmitted to the heat radiating fins 63 and the pipes 53 and 54 is discharged out by the flow of the cooling air from the first housing 4 through the exhaust ports 6.

The liquid coolant, which is cooled while flowing through the first to third path portions 50 to 52 of the heat radiating portion 18, is guided to the inlet pipe 32 of the pump housing 21 through the second pipe 71. The liquid coolant is returned to the reserve tank 29 from the inlet pipe 32. The liquid coolant returned to the reserve tank 29 absorbs again the heat from the IC chip 15, until it is sucked into the pump chamber 28 of the pump housing 21.

The pump chamber 28 of the pump housing 21 communicates with the reserve tank 29 through the communication port 30. Therefore, the liquid coolant in the reserve tank 29 is sucked into the pump chamber 28 through the communication port 30 as the impeller 35 rotates. The liquid coolant sucked in the pump chamber 28 is pressurized and discharged again to the heat radiating portion 18 through the outlet pipe 33.

The above cycle is repeated, so that the heat of the IC chip 15 is successively transmitted to the heat radiating portion 18. The heat transmitted to the heat radiating portion 18 is discharged out of the first housing 4 by the flow of the cooling air passing through the heat radiating portion 18.

The heat radiating portion 18 for radiating the heat of the IC chip 15 has the flat pipes 53 and 54 facing each other, through which heated liquid coolant flows. It also has the heat radiating fins 63 interposed between the pipes 53 and 54. The heat radiating fins 63 extend along the direction of the long axes L1 of the pipes 53 and 54, and the first and second edges 63a and 63b are soldered to the support surfaces 53a and 54a of the pipes 53 and 54.

Thus, the pipes 53 and 54, through which the heated liquid coolant flows, face each other with the heat radiating fins 63 interposed therebetween. Therefore, as indicated by the arrows in FIG. 9, the heat is transmitted from the two pipes 53 and 54 to each of the heat radiating fins 63. Moreover, the contact area where the heat radiating fins 63 are in contact with the pipes 53 and 54 is increased. Therefore, the heat generated by the IC chip 15 and transmitted to the pipes 53 and 54 can be efficiently transferred to the heat radiating fins 63.

Therefore, as the surface temperature of each heat radiating fin 63 rises, the heat is easily transmitted to every part of the heat radiating fin 63 from the pipes 53 and 54. Consequently, the heat generated by the IC chip 15 and absorbed by the liquid coolant can be efficiently discharged from the surfaces of the heat radiating fins 63. Thus, the heat radiating performance of the heat radiating portion 18 improves.

Further, the liquid coolant guided to the heat radiating portion 18 flows from the first path portion 50 located in the upper position to the second path portion 51 located in the lower position. Thus, the liquid coolant flows downward through the third path portion 52. Since it is unnecessary to force the liquid coolant to flow against gravity, the liquid coolant flows through the heat radiating portion 18 with a low resistance.

Therefore, the load of the pump unit 17, which pressurizes and discharges the liquid coolant, is reduced. Accordingly, the liquid coolant is circulated between the pump unit 17 and the heat radiating portion 18 without great driving force.

In addition, each of the pipe 53 of the first path portion 50 located above the heat radiating fins 63 and the pipe 54 of the second path portion 51 located under the heat radiating fins 63 has a smaller thickness in the direction of the thickness direction of the first housing 4. In other words, the short axes S1 of the pipes 53 and 54 extend in the thickness direction of the first housing 4. Thus, the heat radiating portion 18 can be thin and compact. As a result, even if there is no much space in the thickness direction of the first housing 4, the heat radiating portion 18 can be satisfactorily held in the first housing 4.

The present invention is not limited to the first embodiment described above. FIG. 11 shows a second embodiment of the present invention.

The second embodiment is different from the first embodiment in the shape of the third path portion 52 of the heat radiating portion 18. The other constitution of the heat radiating portion 18 is the same as that of the first embodiment. Therefore, the same components are identified by the same reference numerals as those in the first embodiment, and detailed descriptions thereof are omitted.

As shown in FIG. 11, the diameter of the communication path 60 of the third path portion 52 increases, as the distance from the first connection port 58 to the second connection port 59 increases. With the increase of the diameter, the third path portion 52 has a reservoir portion 81 having a large capacity in a lower end portion of the communication path 60. The reservoir portion 81 is located in the connecting portion between the second path portion 51 and the third path portion 52.

According to the above structure, the liquid coolant guided from the first path portion 50 to the third path portion 52 is temporarily stored in the reservoir portion 81. With this storage, the flow rate of the liquid coolant flowing form the third path portion 52 to the second path portion 51 is reduced. Thus, the liquid coolant flows in the second path portion 51 at a rate lower than in the first path portion 50.

As a result, the liquid coolant is in contact with the pipe 54 of the second path portion 51 for a longer time, so that the heat generated by the IC chip 15 and absorbed by the liquid coolant is easily transferred from the pipe 54 to the heat radiating fins 63. Consequently, the heat exchange between the liquid coolant and the heat radiating portion 18 is efficiently performed. Thus, the heat radiating performance of the heat radiating portion 18 improves.

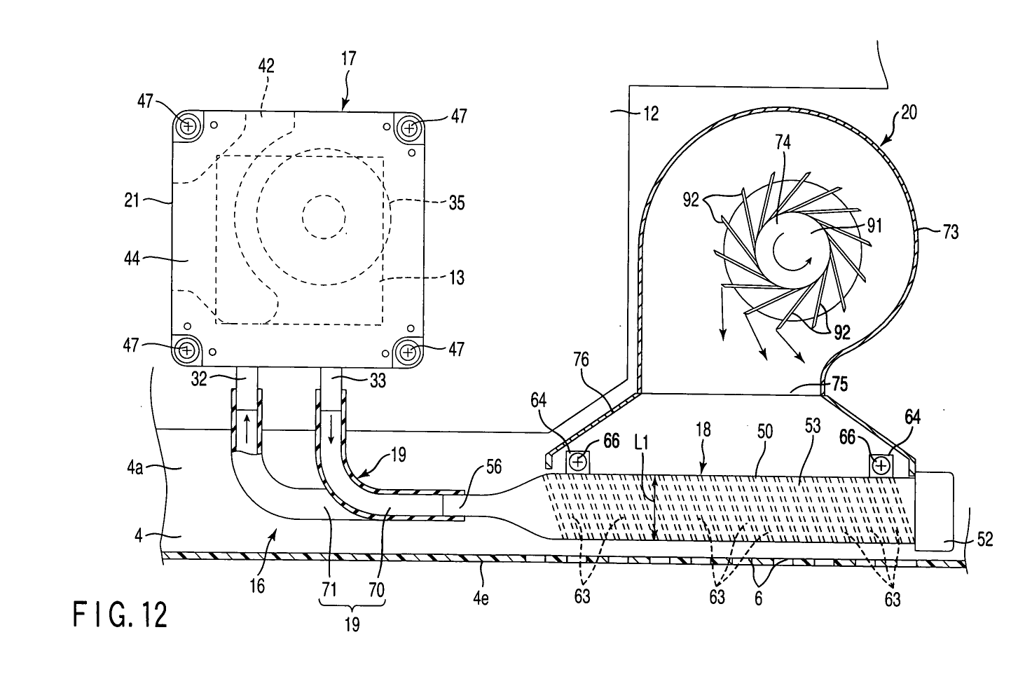

FIG. 12 shows a third embodiment of the present invention.

The third embodiment is different from the first embodiment in the direction of the heat radiating fins 63 of the heat radiating portion 18. The other constitution of the heat radiating portion 18 is the same as that of the first embodiment.

As shown in FIG. 12, the impeller 74 has a hub 91 and a plurality of vanes 92 projecting radially from the circumferential surface of the hub 91. The vanes 92 extend in directions of tangent lines of the hub 91 backward relative to the direction of rotation of the impeller 74. Each vane 92 forms an inclination angle with respect to the circumferential surface of the hub 91. The inclination angle of the vane 92 is determined on the basis of the blow rate of the cooling air.

When the impeller 74 rotates in the direction of the arrow shown in FIG. 12, air is sucked toward the center of rotation of the impeller 74. Then, the air is blown from the tip of the vane 92 to the interior of the casing 73 by centrifugal force. Since the vane 92 extends along the tangent line of the hub 91, the direction of the air blown from the tip of the vane 92 is substantially perpendicular to the vane 92.

Therefore, when the tip of the vane 92 faces the discharge port 75 of the fan casing 73, the direction of flow of the air blown from the tip of the vane 92 has an inclination with respect to the heat radiating portion 18. In other words, the heat radiating fins 63 of the heat radiating portion 18 form an angle relative to the long axes L1 of the pipes 53 and 54 so as to be parallel to the direction of the flow of the air (cooling air) blown from the tips of the vanes 92.

With the above structure, the direction of the flow of the cooling air blown from the discharge port 75 of the fan casing 73 coincides with the direction of the heat radiating fins 63. Therefore, the cooling air easily flows between the adjacent heat radiating fins 63. Consequently, the heat radiating portion 18 can be cooled efficiently; that is, the heat radiating performance of the heat radiating portion 18 improves.

In the first embodiment, the heat radiating portion is arranged along the rear wall of the first housing. However, the present invention is not limited to this arrangement. The heat radiating portion may be arranged along a side wall of the first housing.

Further, in the first embodiment, the pump housing of the pump unit also serves as a heat radiating portion. However, the present invention is not limited to this embodiment. For example, a pump and a heat receiving portion for receiving heat from the CPU may be individually provided in the circulation path.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A cooling unit comprising:
a heat receiving portion thermally connected to a heat generating component;
a heat radiating portion which radiates heat generated by the heat generating component; and
a circulation path which circulates a liquid coolant between the heat receiving portion and the heat radiating portion,
wherein the heat radiating portion includes a first path portion to which the liquid coolant heated by the heat receiving portion is guided, a second path portion located downstream of flow of the liquid coolant from the first path portion, a third path portion connecting the first path portion and the second path portion, and a plurality of heat radiating fins, each of the first and second path portions having a pipe which is flat and through which the liquid coolant flows, the pipe of the first path portion and the pipe of the second path portion having cross sections which are elongated in the same direction and facing each other, and the heat radiating fins being interposed between the two pipes and thermally connected to the two pipes.

2. The cooling unit according to claim 1, further comprising a fan which supplies cooling air to the heat radiating portion.

3. The cooling unit according to claim 2, wherein the heat radiating portion has a cooling air path which allows passage of the cooling air between the first path portion and the second path portion, and the heat radiating fins are located in the cooling air path.

4. The cooling unit according to claim 1, wherein each of the heat radiating fins has a first edge and a second edge which is located at an opposite end from the first edge, the first edge being thermally connected to the pipe of the first path portion, and the second edge being thermally connected to the pipe of the second path portion.

5. The cooling unit according to claim 4, wherein each of the pipes has a long axis and a short axis, the two pipes face each other with the long axes being parallel to each other, and the heat radiating fins are thermally connected to the pipes in a posture that the first and second edges extend along the long axes of the pipes.

6. The cooling unit according to claim 1, wherein the heat receiving portion includes a pump which discharges the liquid coolant toward the heat radiating portion.

7. The cooling unit according to claim 1, wherein the third path portion of the heat radiating portion has a first connection port connected to a downstream end of the first path portion, a second connection port connected to an upstream end of the second path portion, and a communication path connecting the first connection port and the second connection port.

8. The cooling unit according to claim 7, wherein the communication path of the third path portion has a diameter which increases as the distance from the first connection port to the second connection port increases.

9. A cooling unit comprising:
a heat receiving portion thermally connected to a heat generating component;
a heat radiating portion which radiates heat generated by the heat generating component;
a circulation path which circulates a liquid coolant between the heat receiving portion and the heat radiating portion; and
a fan which supplies cooling air to the heat radiating portion,
wherein the heat radiating portion includes a first path portion to which the liquid coolant heated by the heat receiving portion is guided, a second path portion located downstream of flow of the liquid coolant from the first path portion, a third path portion connecting the first path portion and the second path portion, and a plurality of heat radiating fins, each of the first and second path portions having a pipe which is flat and through which the liquid coolant flows, the pipe of the first path portion and the pipe of the second path portion having cross sections which are elongated in the same direction and facing each other to form a cooling air path which allows passage of the cooling air between the pipes, and the heat radiating fins are located in the cooling air path and thermally connected to the two pipes.

10. The cooling unit according to claim 9, wherein each of the heat radiating fins has a first edge and a second edge which is located at an opposite end from the first edge, the first edge being thermally connected to the pipe of the first path portion, and the second edge being thermally connected to the pipe of the second path portion.

11. The cooling unit according to claim 10, wherein each of the pipes has a long axis and a short axis, the two pipes face each other with the long axes being parallel to each other, and the heat radiating fins are thermally connected to the pipes in a posture that the first and second edges extend along the long axes of the pipes.

12. The cooling unit according to claim 9, wherein the heat receiving portion includes a pump which discharges the liquid coolant toward the heat radiating portion.

13. An electronic apparatus comprising:
a housing;
a heat generating component housed in the housing; and
a cooling unit which is housed in the housing and cools the heat generating component, the cooling unit including: a heat receiving portion thermally connected to the heat generating component; a heat radiating portion which radiates heat generated by the heat generating component; and a circulation path which circulates a liquid coolant between the heat receiving portion and the heat radiating portion, wherein the heat radiating portion includes a first path portion to which the liquid coolant heated by the heat receiving portion is guided, a second path portion located downstream of flow of the liquid coolant from the first path portion, a third path portion connecting the first path portion and the second path portion, and a plurality of heat radiating fins, each of the first and second path portions having a pipe which is flat and through which the liquid coolant flows, the pipe of the first path portion and the pipe of the second path portion having cross sections which are elongated in the same direction and facing each other, and the heat radiating fins being interposed between the two pipes and thermally connected to the two pipes.

14. The electronic apparatus according to claim 13, further comprising a fan which supplies cooling air to the heat radiating portion.

15. The electronic apparatus according to claim 14, wherein the housing has a peripheral wall in which an exhaust port is formed, and the heat radiating portion faces the exhaust port.

16. The electronic apparatus according to claim 15, wherein the first path portion and the second path portion are arranged along the peripheral wall of the housing and parallel to each other so as to face each other in a thickness direction of the housing.

17. The electronic apparatus according to claim 16, wherein the heat radiating portion has a cooling air path which allows passage of the cooling air between the first path portion and the second path portion, and the heat radiating fins are located in the cooling air path.

18. The electronic apparatus according to claim 13, wherein the cooling unit includes a pump which discharges the liquid coolant from the heat receiving portion toward the heat radiating portion.
